(19) United States
(12) Patent Application Publication
(10) Pub. No.: US 2024/0333004 A1
(43) Pub. Date: Oct. 3, 2024

(54) POWER SUPPLY APPARATUS

(71) Applicants: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(72) Inventors: Keisuke WAKAZONO, Yokkaichi-shi, Mie (JP); Yuuki SUGISAWA, Yokkaichi-shi, Mie (JP)

(73) Assignees: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(21) Appl. No.: 18/290,760

(22) PCT Filed: Jul. 26, 2021
(86) PCT No.: PCT/JP2021/027593

§ 371 Date: Jan. 20, 2024

(51) Int. Cl. H02J 7/00; B60R 16/03; G01R 31/52; H02J 1/04

(52) U.S. Cl. CPC H02J 7/0047; B60R 16/03; G01R 31/52; H02J 1/04; H02J 2310/40

(57) ABSTRACT

A power supply apparatus includes a bypass circuit, a current conduction circuit, and an anomaly determination unit. The bypass circuit is provided in parallel to a first switching element, and includes a resistor portion, and a current flows therethrough from a power supply unit to a load via the resistor portion. The current conduction circuit is provided between a first conduction path, of a power path, between the bypass circuit and the load, and a second conduction path, which is grounded, and is configured such that, when in a current conduction state, a current flows from the first conduction path to the second conduction path. The anomaly determination unit performs anomaly determination based on a voltage drop at the resistor portion when the current conduction circuit is in the current conduction state.

### CROSS-REFERENCE TO RELATED APPLICATIONS

This application is the U.S. national stage of PCT/JP2021/027593 filed on Jul. 26, 2021, the contents of which are incorporated herein.

### TECHNICAL FIELD

The present disclosure relates to a power supply apparatus.

### BACKGROUND

A power feeding circuit is disclosed in JP 2010-60433A. The power feeding circuit includes a semiconductor switch that is provided between a power supply and a load, and when in a normal mode, supplies a normal current to the load by controlling the semiconductor switch to be turned on, and when in a sleep mode, controls the semiconductor switch to be turned off. Moreover, the power feeding circuit includes a bypass resistor connected in parallel to the semiconductor switch, and when in a sleep mode, supplies a dark current to the load through the bypass resistor.

In the aforementioned technique, a bypass resistor is connected in parallel to a semiconductor switch, and therefore a current flows to a downstream side of the semiconductor switch regardless of the state of the semiconductor switch.

Therefore, it is difficult to perform anomaly determination on the semiconductor switch (e.g., here, the anomaly is a short circuit failure in which the semiconductor switch is not switched off despite being controlled to be turned off). The present disclosure provides a technique for enabling anomaly determination on a switching element to which a circuit is connected in parallel to be performed with high accuracy.

### SUMMARY

A power supply apparatus according to the present disclosure is a power supply apparatus that controls power in a power supply system including a power path that is a conduction path for supplying power from a power supply unit to a load, and a first switching element provided on the power path. The power supply apparatus includes: a bypass circuit that is provided in parallel to the first switching element, and includes a resistor portion, and though which a current flows from the power supply unit to the load via the resistor portion; a current conduction circuit that is provided between a first conduction path, which is a portion of the power path between the bypass circuit and the load, and a second conduction path, which is grounded, and is configured such that, when in a current conduction state, a current flows from the first conduction path to the second conduction path; and an anomaly determination unit configured to perform anomaly determination based on a voltage drop at the resistor portion when the current conduction circuit is in the current conduction state.

### Advantageous Effects

According to the present disclosure, anomaly determination on a switching element to which a circuit is connected in parallel can be performed with high accuracy.

### BRIEF DESCRIPTION OF DRAWINGS

FIG. 1 is a circuit diagram schematically illustrating a configuration of a power supply system of a first embodiment.

FIG. 2 is a diagram for describing a relationship between an elapsed time of discharging from a load and a remaining voltage of the load.

FIG. 3 is a flowchart illustrating an operation flow of a control device in the first embodiment.

FIG. 4 is a flowchart illustrating an operation flow of a control device in a second embodiment.

FIG. 5 is a flowchart illustrating an operation flow of a control device in a third embodiment.

FIG. 6 is a flowchart illustrating an operation flow of a control device in a fourth embodiment.

FIG. 7 is a flowchart illustrating an operation flow of a control device in a fifth embodiment.

FIG. 8 is a flowchart illustrating an operation flow of a control device in a sixth embodiment.

FIG. 9 is a circuit diagram schematically illustrating a configuration of a power supply system of a seventh embodiment.

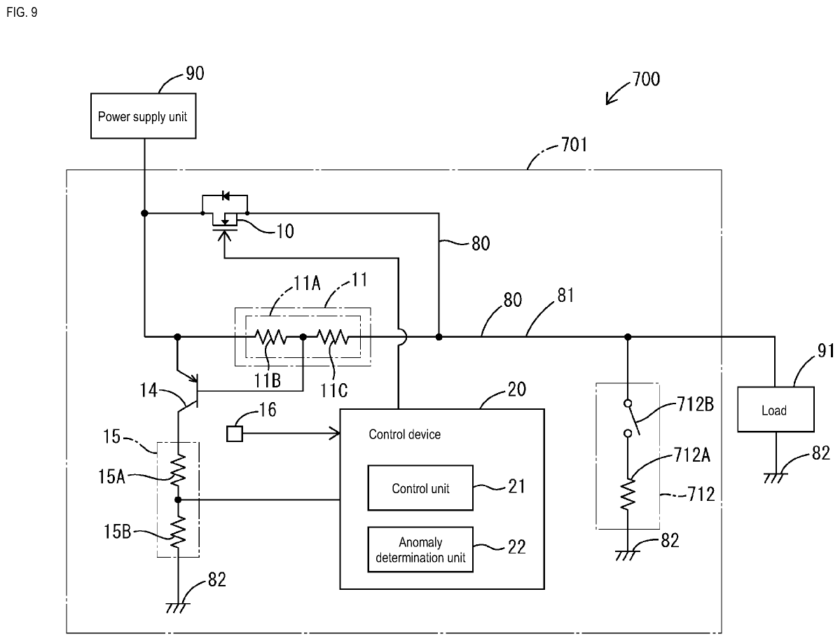

### DETAILED DESCRIPTION OF PREFERRED EMBODIMENTS

Embodiments of the present disclosure will be enumerated and illustrated.

A power supply apparatus according to the present disclosure is a power supply apparatus that controls power in a power supply system including a power path that is a conduction path for supplying power from a power supply unit to a load, and a first switching element provided on the power path. The power supply apparatus includes: a bypass circuit that is provided in parallel to the first switching element, and includes a resistor portion, and in which a current flows from the power supply unit to the load via the resistor portion; a current conduction circuit that is provided between a first conduction path, of the power path, between the bypass circuit and the load, and a second conduction path, which is grounded, and is configured such that, when in a current conduction state, a current flows from the first conduction path to the second conduction path; and an anomaly determination unit configured to perform anomaly determination based on a voltage drop at the resistor portion when the current conduction circuit is in the current conduction state.

With this power supply apparatus, the current flowing through the resistor portion can be increased by causing a current to flow from the first conduction path to the second conduction path via the current conduction circuit, and therefore it can be easily determined whether or not the first switching element is anomalous based on the current flowing through the resistor portion at this moment. Therefore, as a result of perform anomaly determination based on a voltage drop at the resistor portion when the current conduction circuit is in the current conduction state, this power supply apparatus can determine whether the first switching element connected in parallel to the bypass circuit is anomalous with higher accuracy.

One end of the first resistor portion may be short-circuited to the power supply unit, and the other end may be short-circuited to the first conduction path.

According to this configuration, the bypass circuit can be continuously kept in the current conduction state without switching a switch, and therefore resetting of the load due to power supply to the load being stopped by switching a switch to an off state can be suppressed.

The first switching element may perform a normal operation such that, when in an on state, a current is allowed to flow through the power path via the first switching element, and when in an off state, a current flow through the power path via the first switching element is cut off. The power supply apparatus may further include a control unit configured to perform a first switching control in which an instruction to enter an off state is given to the first switching element, and an instruction to enter the current conduction state is given to the current conduction circuit. The anomaly determination unit may perform anomaly determination based on a voltage of the first conduction path when the first switching control is performed.

According to this configuration, whether an anomaly in which the first switching element cannot be switched to an off state (so-called short circuit failure) has occurred can be determined.

The first switching element may perform a normal operation such that, when in an on state, a current is allowed to flow through the power path via the first switching element, and when in an off state, a current flow through the power path via the first switching element is cut off. The power supply apparatus may further include a control unit configured to perform a second switching control in which an instruction to enter an on state is given to the first switching element, and an instruction to enter the current conduction state is given to the current conduction circuit. The anomaly determination unit may perform anomaly determination based on a voltage of the first conduction path when the second switching control is performed.

According to this configuration, whether an anomaly in which the first switching element cannot be switched to an on state (so-called open failure) has occurred can be determined.

A resistance value of the resistor portion, a resistance value of the current conduction circuit in the current conduction state, and a resistance value of the load in a standby state may be set such that a voltage obtained by a voltage between an output potential of the power supply unit when the first switching element is in an off state and a potential of the second conduction path being divided by the resistor portion, the current conduction circuit in the current conduction state, and the load in the standby state exceeds a lower limit voltage that is a minimum voltage needed to maintain the standby state of the load.

According to this configuration, anomaly determination can be performed while keeping the load in the standby state so as to not be reset.

The power supply apparatus may include: a second switching element that is caused to enter an on state when a current flowing through the resistor portion exceeds a threshold current, and is caused to enter an off state when the current is the threshold current or less; and an output circuit configured to output a first signal when the second switching element is in an on state, and output a second signal when the second switching element is in an off state.

According to this configuration, the first signal is output when the current flowing through the resistor portion exceeds the threshold current, and the second signal is output when the current is the threshold current or less. Therefore, erroneous determination caused by an error that occurs at the time of signal conversion (e.g., an error at the time of AD conversion) can be suppressed.

The current conduction circuit may include a constant current circuit, the constant current circuit may perform a constant current operation in which a constant current is caused to flow from the first conduction path to the second conduction path, and the current conduction state may be a state in which the constant current circuit performs the constant current operation.

According to this configuration, the state of the current conduction circuit can be switched between the current conduction state and a cut-off state using the constant current circuit.

The current conduction circuit may include a constant current circuit, the constant current circuit may perform a constant current operation in which a constant current is caused to flow from the first conduction path to the second conduction path, and the current conduction state may be a state in which the constant current circuit performs the constant current operation. The power supply apparatus may further include: a temperature detection unit configured to detect a temperature of the second switching element; and a control unit configured to adjust a current flowing through the constant current circuit based on the temperature of the second switching element.

According to this configuration, the influence of the temperature characteristics of the second switching element can be eliminated.

The current conduction circuit may include a current conduction resistor portion and a current conduction switch, and the current conduction state may be an on state of the current conduction switch.

According to this configuration, the current conduction circuit can be realized with a simple configuration.

The load is a capacitive load, and a period of time for which the anomaly determination unit performs anomaly determination may be larger than a time constant t represented by a following formula (A), where a resistance value of the current conduction circuit when in the current conduction state is denoted by R and a capacitance of the load is denoted by C.

$$τ = R \times C \qquad formula ( A )$$

According to this configuration, erroneous determination due to charge accumulation in the load can be suppressed.

A period of time for which the anomaly determination unit performs anomaly determination may be three times the time constant t or more and nine times the time constant t or less.

As a result of setting the anomaly determination time to a period three times the time constant t or more, the influence of discharging from the load can be reliably eliminated. Therefore, the anomaly determination unit can improve the accuracy of anomaly determination. Meanwhile, as a result of setting the anomaly determination time to a period nine times the time constant t or less, the anomaly determination time can be prevented from being unnecessarily long. Therefore, the anomaly determination unit can perform anomaly determination in a time range appropriate for the vehicle power supply apparatus.

The anomaly determination unit may, upon determining that a vehicle starting switch is switched from an off state to an on state, perform anomaly determination for the period until the load returns to an operating state from a standby state.

According to this configuration, anomaly determination can be performed when a vehicle is started up.

The anomaly determination unit may, upon determining that a vehicle starting switch is switched from an on state to an off state, perform anomaly determination after the load enters a standby state.

According to this configuration, anomaly determination can be performed under circumstances in which the traveling of a vehicle is not influenced.

The load may output a reporting signal when switching from an operating state to a standby state, and the anomaly determination unit may, upon receiving the reporting signal from the load, perform anomaly determination.

According to this configuration, anomaly determination is performed when a reporting signal has been received from a load, and therefore anomaly determination can be more reliably performed during the standby state.

### First Embodiment

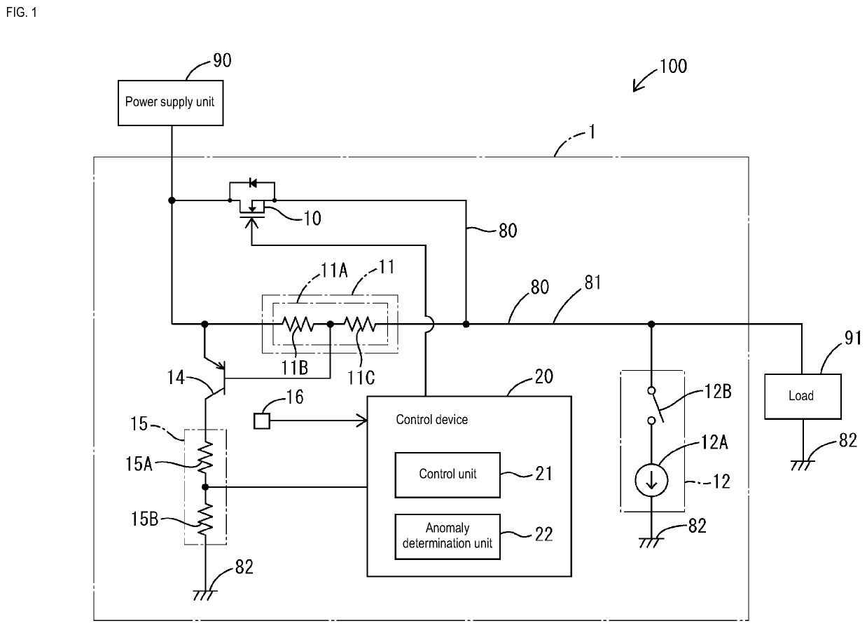

A power supply system 100 shown in FIG. 1 is a system to be mounted in a vehicle. The power supply system 100 includes a power supply unit 90, a load 91, and a power path 80, which is a conduction path through which power based on the power supply unit 90 is supplied to the load 91.

The power supply unit 90 is a battery, for example, and specifically is a lead battery, a lithium-ion battery, or the like. A terminal of the power supply unit 90 on a high potential side is electrically connected to one end of the power path 80, and a terminal of the power supply unit 90 on a low potential side is electrically connected to a second conduction path 82, which is grounded. The output voltage of the power supply unit 90 is applied to the power path 80. Note that the “voltage” in this specification is a voltage relative to a potential of the second conduction path 82.

The load 91 is an electronic device provided in a vehicle, and is an ECU (Electronic Control Unit), for example. The load 91 is switched between an operating state and a standby state. The operating state is a state in which various types of predetermined operations are executed. The standby state is a state in which power consumption is suppressed relative to the operating state, and the operations that are executed in the operating state are restricted. When the load 91 is an ECU, the standby state is a sleep state, for example. The sleep state is a state in which some functions are restricted, a state in which operations are performed intermittently, or the like. When a vehicle starting switch is switched to an on state, upon receiving an instruction from an external device, the load 91 is switched to the operating state, and when the starting switch is switched to an off state, upon receiving an instruction from an external device, the load 91 is switched to the standby state. When the vehicle is an engine-mounted vehicle, the starting switch is an ignition switch, and when the vehicle is an electric car, the starting switch is a power switch. When the voltage applied to the load 91 falls below a lower limit voltage that is the minimum voltage needed to maintain the standby state, the load 91 is reset. When the load 91 is reset, information stored in a volatile memory of the load 91 is erased, communication between the load 91 and an external device stops, and the load 91 stops operating. The load 91 is a capacitive load.

The power supply system 100 includes a power supply apparatus 1. The power supply apparatus 1 is an apparatus that controls electric power. The power supply apparatus 1 includes a first switching element 10, a bypass circuit 11, a current conduction circuit 12, a second switching element 14, an output circuit 15, a temperature detection unit 16, and a control device 20.

The first switching element 10 is a semiconductor switching element, and is a normally-off FET (Field Effect Transistor) in the present embodiment. The first switching element 10 is provided on the power path 80. The first switching element 10 performs a normal operation such that, when in an on state, current is allowed to flow through the power path 80 via the first switching element 10, and when in an off state, a current flow through the power path 80 via the first switching element 10 is cut off.

The bypass circuit 11 includes a resistor portion 11A that is provided in parallel to the first switching element 10. One end of the bypass circuit 11 is electrically connected to a conduction path, of the power path 80, on the power supply unit 90 side relative to the first switching element 10, and the other end of the bypass circuit 11 is electrically connected to a conduction path, of the power path 80, on the load 91 side relative to the first switching element 10. The bypass circuit 11 is configured such that a current flows from the power supply unit 90 to the load 91 through the resistor portion 11A. One end of the resistor portion 11A is short-circuited to the power supply unit 90, and the other end is short-circuited to a first conduction path 81. The first conduction path 81 is a conduction path, of the power path 80, between the bypass circuit 11 (specifically, a connection point between the other end of the bypass circuit 11 and the power path 80) and the load 91. The resistor portion 11A is a structure in which a plurality of resistors are connected in series. One end of this structure is the one end of the resistor portion 11A, and the other end is the other end of the resistor portion 11A. The resistor portion 11A includes a first resistor portion 11B and a second resistor portion 11C. The first resistor portion 11B and second resistor portion 11C are connected in series between the power supply unit 90 and the load 91. The first resistor portion 11B is disposed on the power supply unit 90 side relative to the second resistor portion 11C.

The current conduction circuit 12 is provided between the first conduction path 81 and a second conduction path 82. One end of the current conduction circuit 12 is electrically connected to the first conduction path 81, and the other end is electrically connected to the second conduction path 82. The current conduction circuit 12 is switchable between a current conduction state in which a current flows from the first conduction path 81 to the second conduction path 82 through the current conduction circuit 12, and a cut-off state in which a current flow from the first conduction path 81 to the second conduction path 82 through the current conduction circuit 12 is cut off. The current conduction circuit 12 is configured such that, when in the current conduction state, a current flows from the first conduction path 81 to the second conduction path 82. The current conduction circuit 12 includes a constant current circuit 12A and a third switching element 12B.

The constant current circuit 12A is provided between the first conduction path 81 and the second conduction path 82. The constant current circuit 12A performs a constant current operation in which a constant current is caused to flow from the first conduction path 81 to the second conduction path 82. The third switching element 12B is a semiconductor switching element such as an FET (Field Effect Transistor), for example. The constant current circuit 12A and third switching element 12B are connected in series between the first conduction path 81 and the second conduction path 82. The third switching element 12B is PWM-controlled by the control device 20. The current value of a constant current that is caused to flow by the constant current circuit 12A is adjusted by the duty ratio (ratio of on time in one period) of a PWM signal that is applied to the third switching element 12B. The state in which the constant current circuit 12A performs a constant current operation is a current conduction state, and the state in which the constant current circuit 12A does not perform the constant current operation is a cut-off state. That is, the state in which the third switching element 12B is PWM-controlled is the current conduction state, and the state in which the third switching element 12B is kept in an off state is the cut-off state. Note that, in this specification, when the current value is not specified, the “constant current operation” refers to an operation in which a constant current of a predetermined reference current value is caused to flow.

The second switching element 14 is switched to an on state when the current flowing through the resistor portion 11A exceeds a threshold current, and is switched to an off state when the current falls below the threshold current. The second switching element 14 is a PNP bipolar transistor in the present embodiment. The emitter of the second switching element 14 is short-circuited to an end portion of a portion to be detected that is a portion or the entirety of the resistor portion 11A (first resistor portion 11B in the present embodiment) on the power supply unit 90 side, and the base of the second switching element 14 is short-circuited to an end portion of the portion to be detected on the load 91 side.

The output circuit 15 outputs a first signal (high-level signal) when the second switching element 14 is in an on state, and outputs a second signal (low-level signal) when the second switching element 14 is in an off state. The output circuit 15 is a voltage-dividing circuit that divides the collector voltage of the second switching element 14. The output circuit 15 includes a third resistor portion 15A and a fourth resistor portion 15B. One end of the third resistor portion 15A is short-circuited to the collector of the second switching element 14, and the other end of the third resistor portion 15A is short-circuited to one end of the fourth resistor portion 15B. The other end of the fourth resistor portion 15B is short-circuited to the second conduction path 82. The output circuit 15 divides the voltage between a collector potential of the second switching element 14 and a potential of the second conduction path 82 with the third resistor portion 15A and fourth resistor portion 15B, and outputs the divided voltage. The first signal or second signal output from the output circuit 15 is input to the control device 20.

The resistance value of the resistor portion 11A, the resistance value of the current conduction circuit 12 in the current conduction state (in the present embodiment, the resistance value of the constant current circuit 12A when performing the constant current operation), and the resistance value of the load 91 in the standby state are set such that the voltage obtained by the voltage between an output potential of the power supply unit 90 when the first switching element 10 is in an off state and a potential of the second conduction path 82 being divided by the resistor portion 11A, the current conduction circuit 12 in the current conduction state (in the present embodiment, the constant current circuit 12A that is performing the constant current operation), and the load 91 in the standby state exceeds the lower limit voltage that is the minimum voltage needed to maintain the standby state of the load 91.

The aforementioned threshold current is set, in a state in which the load 91 is in the standby state, and the constant current circuit 12A is performing a constant current operation in which a constant current of a predetermined reference current value is caused to flow, so as to be smaller than the value of a current that flows through the resistor portion 11A when the first switching element 10 has entered an off state normally and larger than the value of a current that flows through the resistor portion 11A when the first switching element 10 has not entered an off state normally. Accordingly, when an instruction to enter an off state is given to the first switching element 10, if the first switching element 10 switches to an off state normally, the value of current flowing through the resistor portion 11A will be larger than the threshold current, and the second switching element 14 is kept in an on state. As a result, the output circuit 15 outputs the first signal (high-level signal). If the first switching element 10 does not switch to an off state normally despite an instruction to enter an off state being given to the first switching element 10, the value of current flowing through the resistor portion 11A will be smaller than the threshold current, and the second switching element 14 is switched to an off state. As a result, the output circuit 15 outputs the second signal (low-level signal). Therefore, upon receiving the first signal, the control device 20 can determine that there is no anomaly, and upon receiving the second signal, the control device 20 can determine that there is an anomaly.

The temperature detection unit 16 detects the temperature of the second switching element 14. The temperature detection unit 16 may be in contact with the second switching element 14, or may not be in contact therewith, and may be disposed in the vicinity of the second switching element 14. The temperature detection unit 16 is configured as a known temperature sensor, for example. A signal indicating the temperature detected by the temperature detection unit 16 is input to the control device 20.

The control device 20 controls the power supply apparatus 1. The control device 20 is an ECU (Electronic Control Unit), for example, and includes a CPU, a memory, an AD converter, a driving circuit, and the like. The control device 20 specifies the temperature of the second switching element 14 based on the signal output from the temperature detection unit 16. The control device 20 includes a control unit 21 and an anomaly determination unit 22.

The control unit 21 controls the first switching element 10 and the third switching element 12B. The control unit 21 causes the constant current circuit 12A to perform a constant current operation by controlling the third switching element 12B. The control unit 21 performs first switching control in which an instruction to enter an off state is given to the first switching element 10, and an instruction to enter the current conduction state is given to the current conduction circuit 12 (the constant current circuit 12A is caused to perform the constant current operation, in the present embodiment). When causing the constant current circuit 12A to perform the constant current operation, the control unit 21 adjusts the current flowing through the constant current circuit 12A based on the temperature of the second switching element 14. The control unit 21 adjusts the current flowing through the constant current circuit 12A by adjusting the duty ratio of a PWM signal applied to the third switching element 12B.

The base-to-emitter voltage at which the second switching element 14 is switched from an off state to an on state may change depending on the temperature of the second switching element 14. Therefore, the control unit 21 adjusts the current flowing through the constant current circuit 12A based on the temperature of the second switching element 14 such that when the first switching element 10 switches to an off state normally, the second switching element 14 is kept in an on state, and when the first switching element 10 does not switches to an off state normally, the second switching element 14 is switched to an off state.

The control unit 21 stores, in advance, correspondence relationship data indicating the correspondence relationship between the temperature of the second switching element 14 and the duty ratio of a PWM signal to be applied to the third switching element 12B, and determines the duty ratio based on the temperature detected by the temperature detection unit 16 and the correspondence relationship data, for example. The correspondence relationship data may be represented by a table, or may also be represented by a computation formula. The control unit 21 adjusts the current value of the constant current caused to flow by the constant current circuit 12A by applying a PWM signal having the duty ratio determined as described above to the third switching element 12B.

The anomaly determination unit 22 performs anomaly detection based on a voltage drop at the resistor portion 11A when the current conduction circuit 12 is in the current conduction state. That is, the anomaly determination unit 22 performs anomaly detection based on a voltage drop at the resistor portion 11A when the constant current circuit 12A is performing a constant current operation. Here, the anomaly is a short circuit failure in which the first switching element 10 does not switches to an off state normally. The anomaly determination unit 22 performs anomaly detection based on a voltage drop at the resistor portion 11A when the first switching control is performed. Upon receiving the first signal from the output circuit 15, the anomaly determination unit 22 determine that there is no anomaly, and upon receiving the second signal, the anomaly determination unit 22 determines that there is an anomaly.

The anomaly determination time during which the anomaly determination unit 22 performs anomaly detection is set in advance. The anomaly determination time is set to a time period larger than the time constant T represented by the following formula (A), where the resistance value of the current conduction circuit 12 in the current conduction state (in the present embodiment, resistance value of the constant current circuit 12A when performing a constant current operation) is denoted by R, and the capacitance of the load 91 is denoted by C.

$$τ = R \times C \qquad formula ( A )$$

Note that the current value in the constant current operation at the time of specifying the resistance value R may be the aforementioned reference current value, an envisioned lower limit current value, an envisioned upper limit current value, or another current value.

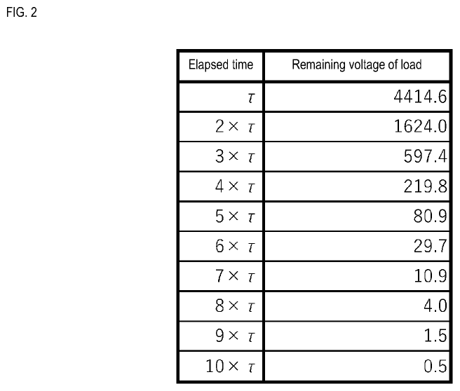

FIG. 2 shows a relationship between the elapsed discharge time and remaining voltage of the load 91, when the load 91 is discharged after the charged voltage of the load 91 has reached the output voltage of the fully charged power supply unit 90 (12V in the present embodiment). The remaining voltage of the load 91 is an error factor of the voltage of the first conduction path 81. As is apparent from FIG. 2, it is preferable that the anomaly determination time is three times the time constant t or more and nine times the time constant t or less. As a result of setting the anomaly determination time to three times the time constant t or more, the influence of discharging from the load 91 can be reliably eliminated. Therefore, the anomaly determination unit 22 can improve the anomaly determination accuracy. On the other hand, as a result of setting the anomaly determination time to nine times the time constant t or less, the anomaly determination time can be prevented from being unnecessarily long. Therefore, the anomaly determination unit 22 can perform anomaly determination in a time range appropriate for a power supply apparatus of a vehicle.

Upon determining that the vehicle starting switch has been switched from an off state to an on state, the anomaly determination unit 22 performs anomaly determination for the period until the load 91 returns to the operating state from the standby state. A signal indicating whether the starting switch is in an on state or an off state is input to the control device 20 from an external device. The anomaly determination unit 22 determines whether the starting switch is in an on state or an off state based on this signal. Upon determining that the starting switch has switched to an on state, the anomaly determination unit 22 immediately performs anomaly determination, and as a result, anomaly determination can be performed for the period until the load 91 returns to the operating state from the standby state.

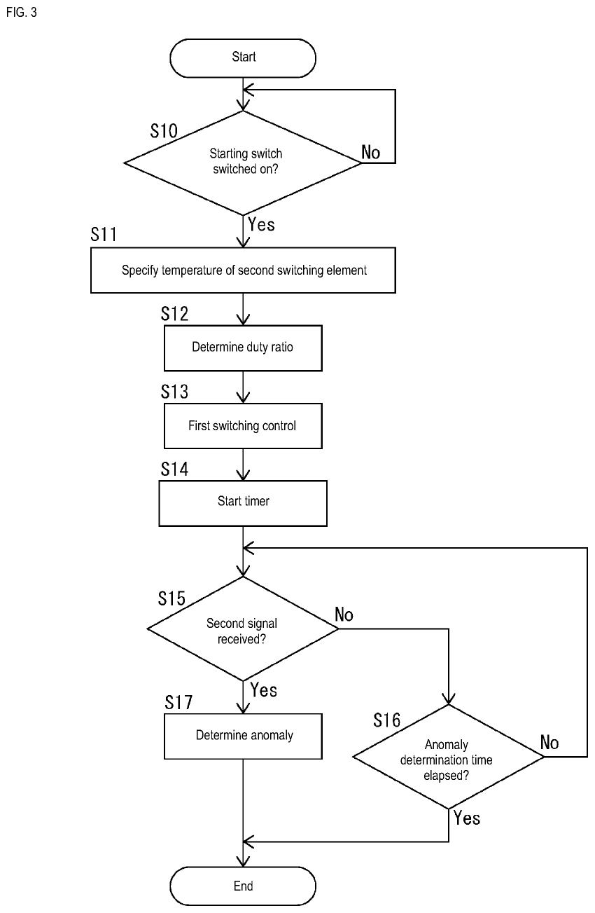

The following description relates to operations performed by the control device 20. When the vehicle starting switch has entered an off state, the control device 20 executes the processing shown in FIG. 3. First, in step S10, the control device 20 determines whether or not the vehicle starting switch has been switched from an off state to an on state. Upon determining that the starting switch has not been switched to an on state (No in step S10), the control device 20 returns the processing to step S10. That is, the control device 20 repeats step S10 until it is determined that the starting switch has switched to an on state.

Upon determining that the starting switch has been switched to an on state (Yes in step S10), the control device 20 specifies the temperature of the second switching element 14 in step S11. Also, in step S12, the control device 20 determines the duty ratio of a PWM signal to be applied to the third switching element 12B based on the temperature specified in step S11. Also, the control device 20 performs the first switching control in step S13. That is, the control device 20 causes the constant current circuit 12A to perform a constant current operation by giving an instruction to enter an off state to the first switching element 10 and applying a PWM signal having the duty ratio determined in step S12 to the third switching element 12B.

The control device 20 starts the operation of a timer in step S14, and, in step S15, determines whether or not the second signal has been received. Upon determining that the second signal has not been received (No in step S15), the control device 20 determines, in step S16, whether or not the elapsed timer operating time has exceeded a preset anomaly determination time. Upon determining that the anomaly determination time has not elapsed (No in step S16), the control device 20 returns the processing to step S15. That is, the control device 20 repeats the determination of whether or not the second signal has been received and the determination of whether or not the anomaly determination time has elapsed, until the control device 20 determines that the second signal has been received or determines that the anomaly determination time has elapsed.

Upon determining that the second signal has been received (Yes in step S15), in step S17, the control device 20 determines that there is an anomaly, and ends the processing shown in FIG. 3. Also, if the anomaly determination time has elapsed without receiving the second signal (Yes in step S16), the control device 20 performs the processing shown in FIG. 3.

The following description relates to effects.

The power supply apparatus 1 of the first embodiment includes the bypass circuit 11 that includes the resistor portion 11A, and is provided in parallel to the first switching element 10. Therefore, without giving an instruction to the first switching element 10 to enter an on state, a dark current can be supplied to the load 91 through the bypass circuit 11. However, in the configuration in which the bypass circuit 11 is included, a current is routed to the downstream side of the first switching element 10 through the bypass circuit 11 regardless of whether or not the first switching element 10 has entered an off state normally, and therefore it is difficult to determine that there is an anomaly in which the first switching element 10 has not switched to an off state normally. However, the power supply apparatus 1 includes the constant current circuit 12A that performs a constant current operation for causing a constant current to flow from the first conduction path 81 to the second conduction path 82, and the anomaly determination unit 22 that performs anomaly determination based on a voltage drop at the resistor portion 11A when the constant current circuit 12A is performing the constant current operation. As a result of the constant current circuit 12A causing a constant current to flow, the current flowing through the resistor portion 11A can be increased, and therefore the power supply apparatus 1 can easily determine whether or not the first switching element 10 is anomalous based on the current flowing through the resistor portion 11A at this moment. Therefore, as a result of performing anomaly determination based on a voltage drop at the resistor portion 11A when the constant current circuit 12A causes a current to flow, the power supply apparatus 1 can determine whether the first switching element 10 connected in parallel to the bypass circuit 11 is anomalous with higher accuracy.

Also, one end of the resistor portion 11A is short-circuited to the power supply unit 90, and the other end is short-circuited to the first conduction path 81. Therefore, the power supply apparatus 1 can cause the bypass circuit 11 to be in the current conduction state without switching a switch, and therefore resetting of the load 91 due to power supply to the load 91 being stopped by switching a switch to an off state can be suppressed.

Also, the first switching element 10 performs a normal operation such that, when in an on state, a current is allowed to flow through the power path 80 via the first switching element 10, and when in an off state, a current flow to the power path 80 via the first switching element 10 is cut off. The control unit 21 performs the first switching control in which an instruction to enter an off state is given to the first switching element 10, and the constant current circuit 12A is caused to perform a constant current operation. The anomaly determination unit 22 performs anomaly determination based on a voltage drop at the resistor portion 11A when the first switching control is performed. Therefore, an anomaly in which the first switching element 10 is not switched to an off state can be reliably determined.

Also, the resistance value of the resistor portion 11A, the resistance value of the constant current circuit 12A when performing a constant current operation, and the resistance value of the load 91 in the standby state are set such that the voltage obtained by the voltage between an output potential of the power supply unit 90 when the first switching element 10 is in an off state and a potential of the second conduction path 82 being divided by the resistor portion 11A, the constant current circuit 12A that is performing the constant current operation, and the load 91 in the standby state exceeds the lower limit voltage that is the minimum voltage needed to maintain the standby state of the load 91. Therefore, anomaly determination can be performed while keeping the load 91 in the standby state so as to not be reset.

Also, the power supply apparatus 1 includes the second switching element 14 and the output circuit 15. The second switching element 14 is kept in an on state when the current flowing through the resistor portion 11A exceeds a threshold current, and is switched to an off state when the current falls below the threshold current. The output circuit 15 outputs the first signal when the second switching element 14 is in an on state, and outputs the second signal when the second switching element 14 is in an off state. According to this configuration, when the current flowing through the resistor portion 11A exceeds the threshold current, the first signal is output, and when this current is the threshold current or less, the second signal is output. Therefore, erroneous determination caused by an error that occurs at the time of signal conversion (e.g., an error at the time of AD conversion) can be suppressed.

Also, the power supply apparatus 1 includes the temperature detection unit 16. The control unit 21 adjusts the current flowing through the constant current circuit 12A based on the temperature of the second switching element 14. Therefore, the influence of the temperature characteristics of the second switching element 14 can be eliminated.

Also, the load 91 is a capacitive load, and the time period during which the anomaly determination unit 22 performs anomaly determination is larger than the time constant t represented by the aforementioned formula (A). Therefore, erroneous determination caused by charges accumulated in the load 91 can be suppressed.

Also, upon determining that the vehicle starting switch has switched from an off state to an on state, the anomaly determination unit 22 performs anomaly determination for the period until the load 91 returns to the operating state from the standby state, and therefore anomaly determination can be performed under circumstances in which the traveling of a vehicle is not influenced.

### Second Embodiment

In a second embodiment, a case will be described in which “upon determining that a vehicle starting switch has been switched from an on state to an off state, an anomaly determination unit performs anomaly determination after a load has entered a standby state”. Note that the second embodiment has the same configuration as the first embodiment except for the operation in which “upon determining that a vehicle starting switch has been switched from an on state to an off state, an anomaly determination unit performs anomaly determination after a load has entered a standby state”. The second embodiment will be described with reference to FIG. 1 illustrating the configuration of the power supply system of the first embodiment.

Upon determining that a vehicle starting switch has been switched from an on state to an off state, an anomaly determination unit 22 performs anomaly determination after a load 91 has entered the standby state. The method of determining whether or not the load 91 has switched to the standby state is not specifically limited, and determination may also be made based on an elapsed time from when the vehicle starting switch was determined to have switched to an off state, for example.

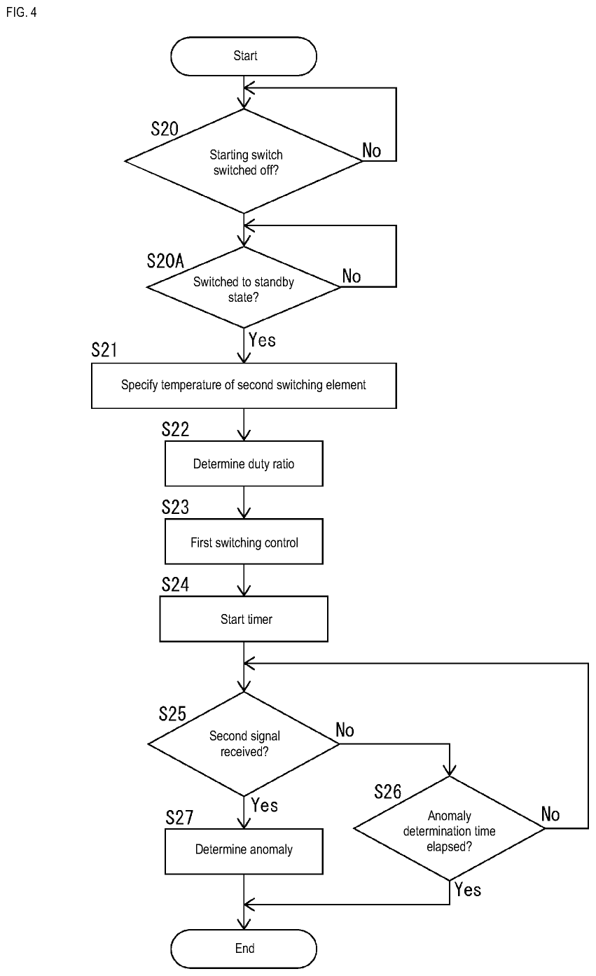

The following description relates to an operation performed by a control device 20 of the second embodiment. When a vehicle starting switch has entered an on state, the control device 20 executes the processing in FIG. 4. The control device 20, first, in step S20, determines whether or not the vehicle starting switch has been switched from an on state to an off state. Upon determining that the starting switch has not been switched to an off state (No in step S20), the control device 20 returns the processing to step S20. That is, the control device 20 repeats step S20 until it is determined that the starting switch has switched to an off state.

Upon determining that the starting switch has switched to an off state (Yes in step S20), the control device 20 determines whether or not the load 91 has switched to the standby state (step S20A). Upon determining that the load 91 has not switched to the standby state (No in step S20A), the control device 20 returns the processing to step S20A, and repeats step S20A until it is determined that the load 91 has switched to the standby state. Upon determining that the load 91 has switched to the standby state (Yes in step S20A), the control device 20 performs the processing of steps S21 to S27. The processing in steps S21 to S27 is the same as the processing in steps S11 to S17 in the first embodiment, and therefore the detailed description thereof will be omitted.

As described above, in the power supply apparatus 1 of the second embodiment, upon determining that the vehicle starting switch has been switched from an on state to an off state, the anomaly determination unit 22 performs anomaly determination after the load 91 has entered the standby state. Therefore, according to the power supply apparatus 1, anomaly determination can be performed under circumstances in which the traveling of a vehicle is not influenced.

### Third Embodiment

In a third embodiment, an example will be described in which the control device 20 described in the first embodiment is communicable with the load 91, and upon receiving a reporting signal indicating that the load 91 has switched to the standby state from the load 91, the control device 20 performs anomaly determination. Note that the third embodiment differs from the first embodiment in that anomaly determination is performed when a reporting signal is received from the control device 20, and is the same in all other respects. Note that the configurations of the power supply system of the third embodiment are the same as those of the first embodiment except that the control device 20 can communicate with the load 91, and therefore the third embodiment will be described with reference to FIG. 1 illustrating the configuration of the power supply system of the first embodiment.

The control device 20 can communicate with the load 91. When a starting switch is switched to an off state, the load 91 is switched from the operating state to the/a standby state in response to an external instruction. Upon being switched from the operating state to the standby state, the load 91 outputs a reporting signal for reporting this fact. The reporting signal is input to the control device 20. Upon receiving the reporting signal from the load 91, an anomaly determination unit 22 of the control device 20 performs anomaly determination.

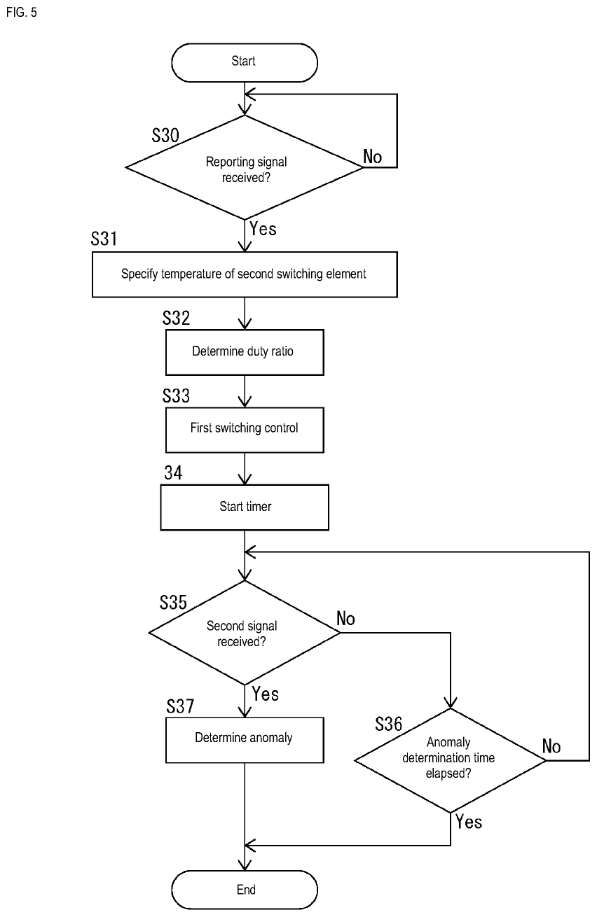

The following description relates to operations performed by the control device 20 of the third embodiment. When the vehicle starting switch has entered an on state, the control device 20 executes the processing shown in FIG. 5. First, in step S30, the control device 20 determines whether or not a reporting signal has been received from the load 91. Upon determining that a reporting signal has not been received (No in step S30), the control device 20 returns the processing to step S30. That is, the control device 20 repeats step S30 until it is determined that a reporting signal has been received. Upon determining that a reporting signal has been received (Yes in step S30), the control device 20 performs the processing of steps S31 to S37. The processing in steps S31 to S37 is the same as the processing in steps S11 to S17 in the first embodiment, and therefore the detailed description thereof will be omitted.

As described above, in the power supply apparatus 1 of the third embodiment, upon receiving a reporting signal from the load 91, the anomaly determination unit 22 performs anomaly determination. Therefore, according to this configuration, an anomaly can be reliably determined during the standby state.

### Fourth Embodiment

The first, second, and third embodiments are configured to determine a short circuit failure of the first switching element. In contrast, the fourth embodiment is configured to determine an open failure of the first switching element. The fourth embodiment differs from the first embodiment only in terms of the control method performed by the control device 20. In the following description, the constituent elements that are the same as those of the first embodiment are given the same reference numerals, and detailed description thereof will be omitted.

The second switching element 14 is switched to an on state when the current flowing through the resistor portion 11A exceeds a threshold current, and is switched to an off state when this current falls below the threshold current. The threshold current is set, in a state in which the load 91 is in the standby state, and the constant current circuit 12A is performing a constant current operation in which a constant current of a predetermined reference current value is caused to flow, so as to be larger than the value of a current that flows through the resistor portion 11A when the first switching element 10 has entered an on state normally and smaller than the value of a current that flows through the resistor portion 11A when the first switching element 10 has not has entered an on state normally. Accordingly, when an instruction to enter an on state is given to the first switching element 10, if the first switching element 10 switches to an on state normally, the value of current flowing through the resistor portion 11A will be smaller than the threshold current, and the second switching element 14 is switched to an off state. As a result, the output circuit 15 outputs the second signal (low-level signal). If the first switching element 10 does not switches to an on state normally despite an instruction to enter an on state being given to the first switching element 10, the value of current flowing through the resistor portion 11A will remain larger than the threshold current, and the second switching element 14 is kept to be in an on state. As a result, the output circuit 15 outputs the first signal (high-level signal). Therefore, upon receiving the second signal, the control device 20 can determine that there is no anomaly, and upon receiving the first signal, the control device 20 can determine that there is an anomaly.

The control unit 21 performs second switching control in which an instruction to enter an on state is given to the first switching element 10, and an instruction to enter a current conduction state is given to a current conduction circuit 12. The anomaly determination unit 22 performs anomaly determination based on a voltage drop at the resistor portion 11A when the second switching control is performed. Here, the anomaly is an open failure in which the first switching element 10 does not switched to an on state normally. Upon receiving the first signal from the output circuit 15, the anomaly determination unit 22 determine that there is no anomaly, and upon receiving the second signal, the anomaly determination unit 22 determines that there is an anomaly.

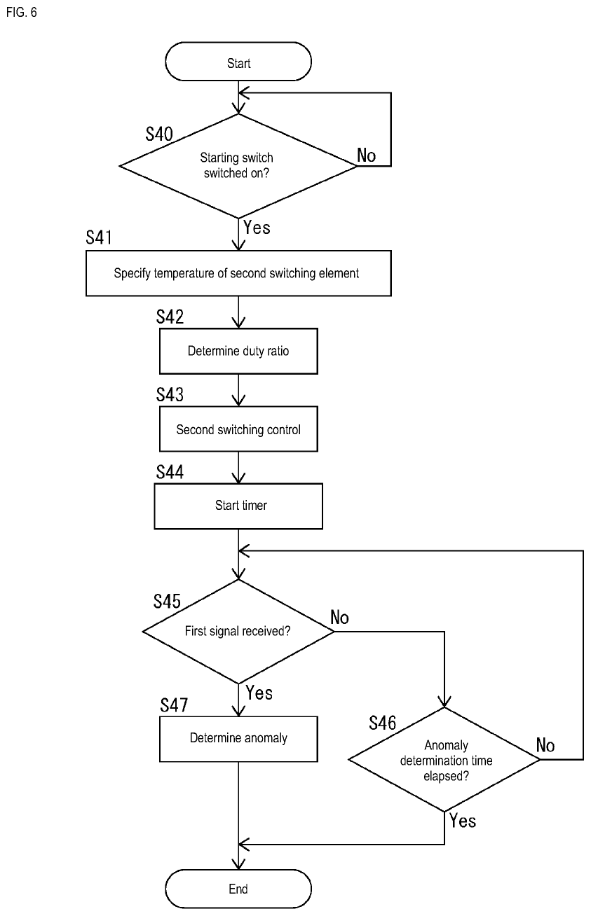

The following description relates to operations performed by the control device 20 of the fourth embodiment. When a vehicle starting switch has entered an off state, the control device 20 executes the processing shown in FIG. 6. First, in step S40, the control device 20 determines whether or not the vehicle starting switch has been switched from an off state to an on state. Upon determining that the starting switch has not been switched to an on state (No in step S40), the control device 20 returns the processing to step S40. That is, the control device 20 repeats step S40 until it is determined that the starting switch has been switched to an on state.

Upon determining that a starting switch has switched to an on state (Yes in step S40), the control device 20 specifies the temperature of the second switching element 14 in step S41. Also, the control device 20 determines, in step S42, the duty ratio of a PWM signal to be applied to the third switching element 12B based on the temperature specified in step S41. Then, the control device 20 performs the second switching control in step S43. That is, the control device 20 causes the constant current circuit 12A to perform a constant current operation by giving an instruction to enter an on state to the first switching element 10, and applying a PWM signal having the duty ratio determined in step S42 to the third switching element 12B.

The control device 20 starts the operation of a timer in step S44, and, in step S45, determines whether or not the first signal has been received. Upon determining that the first signal has not been received (No in step S45), the control device 20 determines, in step S46, whether or not the elapsed timer operating time has exceeded a preset anomaly determination time. Upon determining that the anomaly determination time has not elapsed (No in step S46), the control device 20 returns the processing to step S45. That is, the control device 20 repeats the determination of whether or not the first signal has been received and the determination of whether or not the anomaly determination time has elapsed, until the control device 20 determines that the first signal has been received or determines that the anomaly determination time has elapsed.

Upon determining that the first signal has been received (Yes in step S45), in step S47, the control device 20 determines that there is an anomaly, and ends the processing shown in FIG. 6. Also, if the anomaly determination time has elapsed without receiving the first signal (Yes in step S46), the control device 20 performs the processing shown in FIG. 6.

As described above, according to the power supply apparatus 1 of the fourth embodiment, an anomaly in which the first switching element 10 does not switch to an on state (so-called an open failure) can be determined.

### Fifth Embodiment

The power supply apparatus 1 of the fourth embodiment is configured such that “the anomaly determination unit, upon determining that the vehicle starting switch has been switched from an off state to an on state, performs anomaly determination for the period until the load switches from the standby state to the operating state “. In contrast, a power supply apparatus 1 of the fifth embodiment is configured such that “the anomaly determination unit, upon determining that the vehicle starting switch has been switched from an on state to an off state, performs anomaly determination after the load enters the standby state”. The fifth embodiment differs from the fourth embodiment only in terms of the timing at which anomaly determination is performed. In the following description, differences from the fourth embodiment will be mainly described, and the description of common portions will be omitted.

Upon determining that a vehicle starting switch has been switched from an on state to an off state, an anomaly determination unit 22 performs anomaly determination after a load 91 enters the standby state. The method of determining whether or not the load 91 has switched to the standby state is not specifically limited, and determination may also be made based on an elapsed time from when the vehicle starting switch was determined to have switched to an off state, for example.

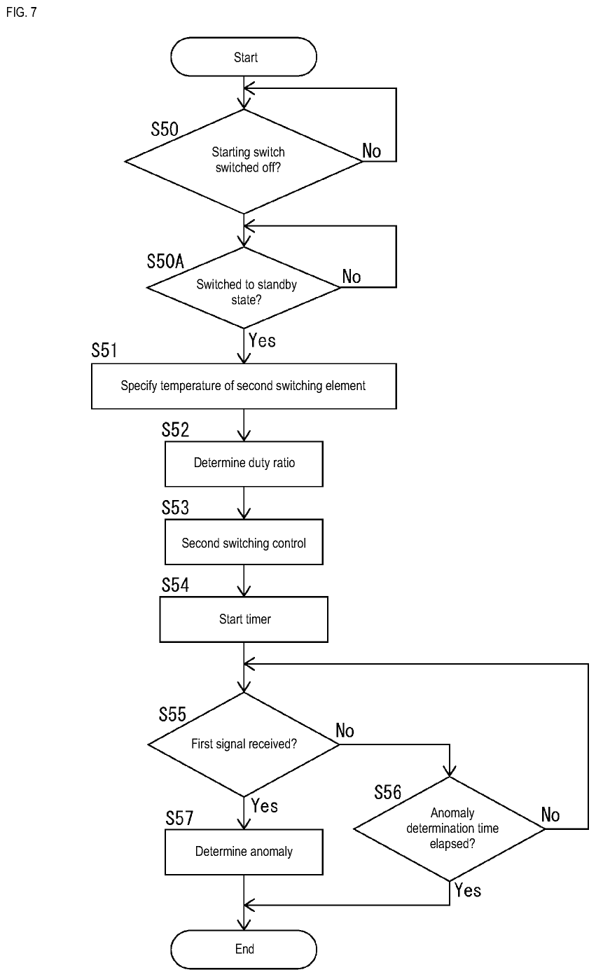

The following description relates to operations performed by the control device 20 of the fifth embodiment. When the vehicle starting switch has entered an on state, the control device 20 executes the processing shown in FIG. 7. First, in step S50, the control device 20 determines whether or not the vehicle starting switch has been switched from an on state to an off state. Upon determining that the starting switch has not been switched to an off state (No in step S50), the control device 20 returns the processing to step S50. That is, the control device 20 repeats step S50 until it is determined that the starting switch has been switched to an off state.

Upon determining that the starting switch has been switched to an off state (Yes in step S50), the control device 20 determines whether or not the load 91 has switched to the standby state (step S50A). Upon determining that the load 91 has not switched to the standby state (No in step S50A), the control device 20 returns the processing to step S50A and repeats step S50A until it is determined that the load 91 has switched to the standby state. Upon determining that the load 91 has switched to the standby state (Yes in step S50A), the control device 20 performs the processing in steps S51 to S58. The processing in steps S51 to S58 is the same as the processing in steps S41 to S48 in the fourth embodiment, and therefore detailed description thereof will be omitted.

As described above, in the power supply apparatus 1 of the fifth embodiment, upon determining that the vehicle starting switch has been switched from an on state to an off state, the anomaly determination unit 22 performs anomaly determination after the load 91 has entered the standby state. Therefore, according to the power supply apparatus 1, anomaly determination can be performed under circumstances in which traveling of the vehicle is not influenced.

### Sixth Embodiment

The power supply apparatus 1 of the fourth embodiment is configured such that “the anomaly determination unit, upon determining that the vehicle starting switch has been switched from an off state to an on state, performs anomaly determination for the period until the load switches from a standby state to an operating state”. In contrast, a power supply apparatus 1 of the sixth embodiment is configured such that “upon receiving a reporting signal from a load, an anomaly determination unit performs anomaly determination”. The sixth embodiment differs from the fourth embodiment only in terms of the timing at which anomaly determination is performed. In the following description, differences from the fourth embodiment will be mainly described, and the description of common portions will be omitted.

Upon switching from the standby state to the operating state, the load 91 outputs a reporting signal. Upon receiving a reporting signal from the load 91, the anomaly determination unit 22 performs anomaly determination.

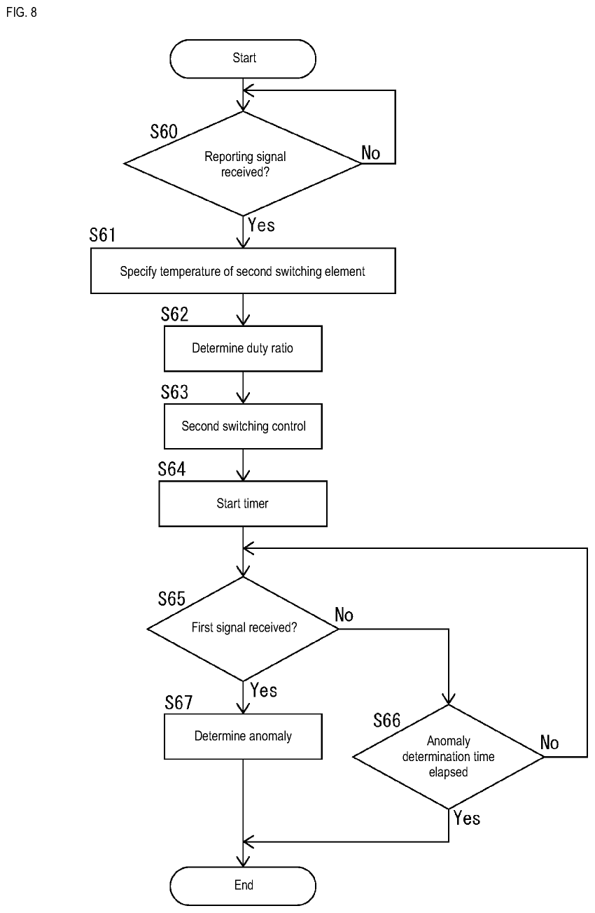

The following description relates to operations performed by the control device 20 of the sixth embodiment. When the vehicle starting switch has entered an on state, the control device 20 executes the processing shown in FIG. 8. First, in step S60, the control device 20 determines whether or not a reporting signal has been received from the load 91. Upon determining that a reporting signal has not been received (No in step S60), the control device 20 returns the processing to step S60. That is, the control device 20 repeats step S60 until a reporting signal is determined to have been received.

Upon determining that a reporting signal has been received (Yes in step S60), the control device 20 performs the processing in steps S61 to S68. The processing in steps S61 to S68 is the same as the processing in steps S41 to S48 in the fourth embodiment, and therefore detailed description thereof will be omitted.

As described above, in the power supply apparatus 1 of the sixth embodiment, upon receiving a reporting signal from the load 91, the anomaly determination unit 22 performs anomaly determination. Therefore, according to the power supply apparatus 1, anomaly determination can be performed after the load 91 has reliably entered the standby state.

### Seventh Embodiment

A power supply apparatus 701 of a seventh embodiment differs from the power supply apparatus 1 of the first embodiment in that the current conduction circuit 12 includes a current conduction resistor portion and a current conduction switch. In the following description, the constituent elements that are the same as those of the first embodiment are given the same reference numerals, and detailed description thereof will be omitted.

A power supply system 700 of the seventh embodiment includes a power supply apparatus 701. The power supply apparatus 701 includes a current conduction circuit 712. The current conduction circuit 712 includes a current conduction resistor portion 712A and a current conduction switch 712B. The current conduction resistor portion 712A and the current conduction switch 712B are connected in series to each other. The current conduction resistor portion 712A is a structure in which a plurality of resistors are connected in series. The current conduction state is an on state of the current conduction switch 712B and the cut-off state is an off state of the current conduction switch 712B. The current conduction circuit 712 is configured such that when the current conduction switch 712B is in an on state, a current flows from the first conduction path 81 to the second conduction path 82.

The control unit 21 performs first switching control in which an instruction to enter an off state is given to the first switching element 10 and an instruction to enter an on state is given to the current conduction switch 712B. The anomaly determination unit 22 performs anomaly determination based on a voltage drop at the resistor portion 11A when the current conduction switch 712B is in an on state.

As described above, according to the power supply apparatus 701 of the seventh embodiment, the current conduction circuit 12 can be realized with a simple configuration.

### OTHER EMBODIMENTS

The present disclosure is not limited to the embodiments illustrated by the above description and drawings. For example, the features of the embodiments described above and below can be combined as long as no contradiction arises. Also, any feature of the embodiments described above and below may be omitted provided they are not explicitly indicated as being essential. Furthermore, the embodiments described above may be modified as follows.

In the embodiments described above, the bypass circuit 11 does not include a switch, but may include a switch.

In the embodiments described above, a detection circuit that detects switching of the load 91 to the operating state, and a switching circuit that switches the first switching element 10 to an on state when the detection circuit has detected switching of the load 91 to the operating state may be provided. According to this configuration, when the load 91 has switched to the operating state, the first switching element 10 can be immediately switched to an on state, and power can be supplied to the load 91. The detection circuit may perform detection based on a voltage of the first conduction path 81, and may also perform detection based on the current flowing through the first conduction path 81.

In the first, second, and third embodiments described above, a configuration was adopted in which it is determined that there is an anomaly if the second signal has been received in a period starting from when the first switching control is started to when the anomaly determination time elapses, but another configuration may also be adopted. For example, a configuration may also be adopted in which it is determined that there is an anomaly if the first signal has not been received in a period starting from when the first switching control is started to when the anomaly determination time elapses. Alternatively, anomaly determination is performed based on a voltage drop at the resistor portion at a time when the anomaly determination time has elapsed since the first switching control was started. Specifically, it is determined that there is an anomaly if it is determined that the second signal has been received at a time when the anomaly determination time has elapsed from when the first switching control was started. In the fourth, fifth, and sixth embodiments, a configuration was adopted in which it is determined that there is an anomaly if the first signal has been received in a period starting from when the second switching control is started to when the anomaly determination time elapses, but another configuration may also be adopted. For example, a configuration may also be adopted in which it is determined that there is an anomaly if the second signal has not been received in a period starting from when the second switching control is started to when the anomaly determination time elapses. Alternatively, anomaly determination may be performed based on a voltage drop at the resistor portion at a time when the anomaly determination time has elapsed since the second switching control was started. Specifically, anomaly determination may be performed if it is determined that the first signal has been received at a time when the anomaly determination time has elapsed from when the second switching control was started.

It should be noted that the embodiments disclosed herein should be considered as examples in all respects and not restrictive. The scope of the present disclosure is not limited to the embodiments disclosed herein, and is intended to include all modifications within the scope indicated by the claims or within a scope equivalent to the claims.

1. A power supply apparatus that controls power in a power supply system including a power path that is a conduction path for supplying power from a power supply unit to a load, and a first switching element provided on the power path, the power supply apparatus comprising:
a bypass circuit that is provided in parallel to the first switching element, and includes a resistor portion, and in which a current flows from the power supply unit to the load via the resistor portion;
a current conduction circuit that is provided between a first conduction path, of the power path, between the bypass circuit and the load, and a second conduction path, which is grounded, and is configured such that, when in a current conduction state, a current flows from the first conduction path to the second conduction path; and
an anomaly determination unit configured to determine an anomaly based on a voltage drop at the resistor portion when the current conduction circuit is in the current conduction state.

2. The power supply apparatus according to claim 1, wherein one end of the resistor portion is short-circuited to the power supply unit, and the other end is short-circuited to the first conduction path.

3. The power supply apparatus according to claim 1,
wherein the first switching element performs a normal operation such that, when in an on state, a current is allowed to flow through the power path via the first switching element, and when in an off state, a current flow through the power path via the first switching element is cut off,
the power supply apparatus further comprises a control unit that performs first switching control in which an instruction to enter an off state is given to the first switching element, and an instruction to enter the current conduction state is given to the current conduction circuit, and
the anomaly determination unit determines an anomaly based on a voltage of the first conduction path when the first switching control is performed.

4. The power supply apparatus according to claim 1,
wherein the first switching element performs a normal operation such that, when in an on state, a current is allowed to flow through the power path via the first switching element, and when in an off state, a current flow through the power path via the first switching element is cut off,
the power supply apparatus further comprises a control unit that performs second switching control in which an instruction to enter an on state is given to the first switching element, and an instruction to enter the current conduction state is given to the current conduction circuit, and
the anomaly determination unit determines an anomaly based on a voltage of the first conduction path when the second switching control is performed.

5. The power supply apparatus according to claim 1,
wherein a resistance value of the resistor portion, a resistance value of the current conduction circuit in the current conduction state, and a resistance value of the load in a standby state are set such that a voltage obtained by dividing a voltage between an output potential of the power supply unit when the first switching element is in an off state and a potential of the second conduction path by the resistor portion, the current conduction circuit in the current conduction state, and the load in the standby state exceeds a lower limit voltage that is a minimum voltage needed to maintain the standby state of the load.

6. The power supply apparatus according to claim 1, further comprising:
a second switching element that is caused to enter an on state when a current flowing through the resistor portion exceeds a threshold current, and is caused to enter an off state when the current is the threshold current or less; and
an output circuit configured to output a first signal when the second switching element is in an on state, and output a second signal when the second switching element is in an off state.

7. The power supply apparatus according to claim 1,
wherein the current conduction circuit includes a constant current circuit,
the constant current circuit performs a constant current operation in which a constant current is caused to flow from the first conduction path to the second conduction path, and
the current conduction state is a state in which the constant current circuit performs the constant current operation.

8. The power supply apparatus according to claim 6,
wherein the current conduction circuit includes a constant current circuit,
the constant current circuit performs a constant current operation in which a constant current is caused to flow from the first conduction path to the second conduction path,
the current conduction state is a state in which the constant current circuit performs the constant current operation, and
the power supply apparatus further comprises:
a temperature detection unit configured to detect a temperature of the second switching element; and
a control unit configured to adjust a current flowing through the constant current circuit based on the temperature of the second switching element.

9. The power supply apparatus according to claim 1,
wherein the current conduction circuit includes a current conduction resistor portion and a current conduction switch, and
the current conduction state is an on state of the current conduction switch.

10. The power supply apparatus according to claim 1,
wherein the load is a capacitive load, and
a period of time in which the anomaly determination unit determines an anomaly is larger than a time constant t represented by a following formula (A), where a resistance value of the current conduction circuit in the current conduction state is denoted as R and a capacitance of the load is denoted as C.
$$τ = R \times C \qquad formula ( A )$$

11. The power supply apparatus according to claim 10, wherein a period of time in which the anomaly determination unit determines an anomaly is three times the time constant t or more and nine times the time constant t or less.

12. The power supply apparatus according to claim 1, wherein upon determining that a vehicle starting switch is switched from an off state to an on state, the anomaly determination unit determines an anomaly in a period in which the load returns to an operating state from a standby state.

13. The power supply apparatus according to claim 1, wherein, upon determining that a vehicle starting switch is switched from an on state to an off state, the anomaly determination unit determines an anomaly after the load enters a standby state.

14. The power supply apparatus according to claim 1,
wherein the load outputs a reporting signal upon switching from an operating state to a standby state, and
the anomaly determination unit, upon receiving the reporting signal from the load, determines an anomaly.
